(19) United States
(12) Patent Application Publication
(10) Pub. No.: US 2006/0258047 A1
(43) Pub. Date: Nov. 16, 2006

(54) Method for laser cutting and method of producing function elements

(75) Inventors: Masayuki Nishiwaki, Yoshikawa-shi (JP); Junichiro Iri, Yokohama-shi (JP); Toshiaki Akasaka, Suginami-ku (JP); Sadayuki Sugama, Tsukuba-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: Canon Kabushiki Kaisha, Ohta-ku (JP)

(21) Appl. No.: 11/416,682

(22) Filed: May 2, 2006

(30) Foreign Application Priority Data
May 11, 2005 (JP) 2005-138469

(51) Int. Cl. H01L 21/00

(52) U.S. Cl. 438/107

(57) ABSTRACT

At least one exemplary embodiment is directed to a method of cutting a member by irradiating the member with a laser beam including the steps of forming an internal processing area in the depth direction of the member by focusing the laser beam inside the member and forming a melt area extending in the depth direction of the member by focusing the laser beam on the surface of the member or inside the member.

### BACKGROUND OF THE INVENTION

1. Field of the Invention

The present invention relates to a method of cutting a member by irradiating the member with a laser beam and a method of producing function elements by separating a plurality of function elements from a substrate by irradiating the function elements with a laser beam.

2. Description of the Related Art

A conventional method of cutting a member, is a blade dicing method. According to the blade dicing method, a semiconductor substrate is cut by grinding the substrate with an abrasive material provided on the surface of a high-speed rotating disk-shaped blade, which can have a width of several ten to several hundred micrometers. When employing this method, usually, cold water is sprayed at the cutting surface of the substrate to reduce heat and wearing caused by the cutting. However, when this method is employed to cut a substrate, fine particles of the substrate being cut and the abrasive material from the blade are produced during the cutting operation and are mixed with the cooling water. Thus, the particles spread throughout a wide area including the cutting surface on the substrate.

To solve this problem, the substrate can be cut in a dry environment where cooling water is not used. To cut the substrate in such an environment, a method of cutting the substrate by focusing a laser beam, which has a predetermined wavelength easily absorbed at the surface of the substrate, on the surface of the substrate can be employed.

Japanese Patent Laid-Open Nos. 2002-192370 and 2002-205180 discuss methods of cutting a substrate by focusing a laser beam, which has a predetermined wavelength easily absorbed inside the substrate, inside the substrate. According to such methods, an internal processing area is formed inside a substrate that is provided as a member to be cut by focusing a laser beam, which has a predetermined wavelength that can be easily transmitted through the substrate, inside the substrate. The internal processing area is the origin of the cutting. At the origin, a crack develops in the thickness direction of the substrate. According to such methods, melt areas are not formed on the surface of the substrate. Therefore, heat-generation and recoagulation can be prevented and/or reduced.

Japanese Patent Laid-Open No. 2002-205180 discusses a method of forming a plurality of internal processing areas along the incident direction of the laser beam by changing the depth of the focal point of the laser beam.

However, when a method of cutting a substrate by developing a melt area inside the substrate by focusing a laser beam on the surface of the substrate is employed, the areas near the cut section on the surface of the substrate are also typically melted. Thus, the surface of the substrate in areas other that the cut section (i.e., cutting line) can be damaged. Moreover, sometimes processing debris from inside the substrate is sprayed onto the surface of the substrate.

According to the method discussed above, the origin of the crack formed to cut the substrate is provided at the tip of an internal processing area, which is formed by focusing a laser beam, closest to the surface of the substrate. Therefore, it can be difficult to control the crack development from the origin so that the crack develops in a predetermined direction at a predetermined position.

In particular, the development direction of a crack formed in a substrate (i.e., member to be cut) composed of a crystalline material, such as a silicon wafer, is affected by the crystal orientation. Therefore, when there is a minor misalignment in the crystal orientation to the substrate surface and the cutting line caused by a production error generated during the production of the silicon substrate and devices, the crack often deviates from the cutting line when the crack develops toward the substrate surface. In such a case, there is a high possibility that the deviated crack will cause damage to the logic circuits of the semiconductor devices provided on the substrate surface.

### SUMMARY OF THE INVENTION

An exemplary embodiment of the present invention is directed towards a method of cutting a member by irradiating the member with a laser beam to form a crack connecting an internal processing area and the surface of the member so that the crack does not deviate from the cutting line provided on the surface of the member.

Another exemplary embodiment of the present invention is directed towards a method of producing function elements by separating the function elements from a substrate to form a crack connecting an internal processing area of the substrate on which the function elements are formed and the surface of the substrate so that the crack does not deviate from the cutting line provided on the surface of the substrate.

Another exemplary embodiment of the present invention is directed towards a method of cutting a member by irradiating the member with a laser beam includes steps of forming an internal processing area in the depth direction of the member by focusing the laser beam inside the member and forming a melt area extending in the depth direction of the member by focusing the laser beam on the surface of the member or inside the member.

Another exemplary embodiment of the present invention is directed towards a method of producing function elements by separating a plurality of function elements from a substrate by irradiating the function elements with a laser beam, the method including the steps of forming an internal processing area extending inside the substrate in the depth direction of the substrate. The internal processing area being formed by focusing the laser beam inside the substrate, forming a melt area extending in the depth direction of the substrate, the melt area being formed by focusing the laser beam at the surface of the substrate or inside the substrate, and separating the function elements from the substrate.

Further features of the present invention will become apparent from the following description of exemplary embodiments (with reference to the attached drawings).

### BRIEF DESCRIPTION OF THE DRAWINGS

FIG. 1A illustrates a perspective view of a silicon substrate; FIG. 1B illustrates an enlarged perspective view of a part of the silicon substrate shown in FIG. 1A; and FIG. 1C illustrates a cross-sectional view of the part of the silicon substrate shown in FIG. 1B.

FIG. 2 illustrates a cross-sectional view of internal processing areas formed inside a silicon substrate.

FIG. 3A illustrates a processing apparatus configured to carry out internal processing and melt processing from the substrate surface; FIG. 3B illustrates a processing apparatus configured to carry out internal processing and melt processing for forming a melt area inside the substrate; and FIG. 3C illustrates a processing apparatus configured to use only one light source to carry out internal processing and melt processing.

FIG. 4 is a cross-sectional view illustrating melt processing using a laser beam that is absorbed at the surface of a silicon substrate.

FIG. 5A is a cross-sectional view illustrating melt processing using a laser beam that is absorbed inside a silicon substrate; and FIG. 5B is a cross-sectional view illustrating melt processing carried out by moving a focal point inside a substrate from the back side of the substrate toward the front side.

### DESCRIPTION OF THE EMBODIMENTS

The following description of at least one exemplary embodiment is merely illustrative in nature and is in no way intended to limit the invention, its application, or uses.

Processes, techniques, apparatus, and materials as known by one of ordinary skill in the relevant art may not be discussed in detail but are intended to be part of the enabling description where appropriate.

In all of the examples illustrated and discussed herein any specific values, for example the positioning of the laser focus, should be interpreted to be illustrative only and non limiting. Thus, other examples of the exemplary embodiments could have different values.

Notice that similar reference numerals and letters refer to similar items in the following figures, and thus once an item is defined in one figure, it may not be discussed for following figures.

According to an exemplary embodiment of the present invention, a plurality of devices 10a (e.g., logic device), (e.g., semiconductor devices), are provided on the surface of a silicon substrate 10. Note in the examples that follow the devices 10a are referred to as logic devices, however exemplary embodiments are not limited to separating logic devices, and thus any type of device deposited on a substrate that needs to be separated falls within at least one exemplary embodiment. Below, methods of cutting the silicon substrate 10 to separate each of the logic devices 10a into individual device chips will be described.

The silicon substrate 10 has a front surface and a back surface. According to an exemplary embodiment of the present invention, the silicon substrate 10 is cut by irradiating the inside portion of the substrate and the front surface of substrate, where a plurality of semiconductor circuits are provided, with a laser beam having predetermined wavelength from the front side of the substrate. According to the following descriptions, a surface of the substrate on which the semiconductor circuits are provided is referred to as the “front surface.” However, when a surface of the substrate is simply addressed as a “substrate surface,” this surface can be either the front surface or the back surface of the substrate. When cutting a member whose front and back surfaces do not have to be distinguished, the entire outer surface of the member will be referred to as the “surface.”

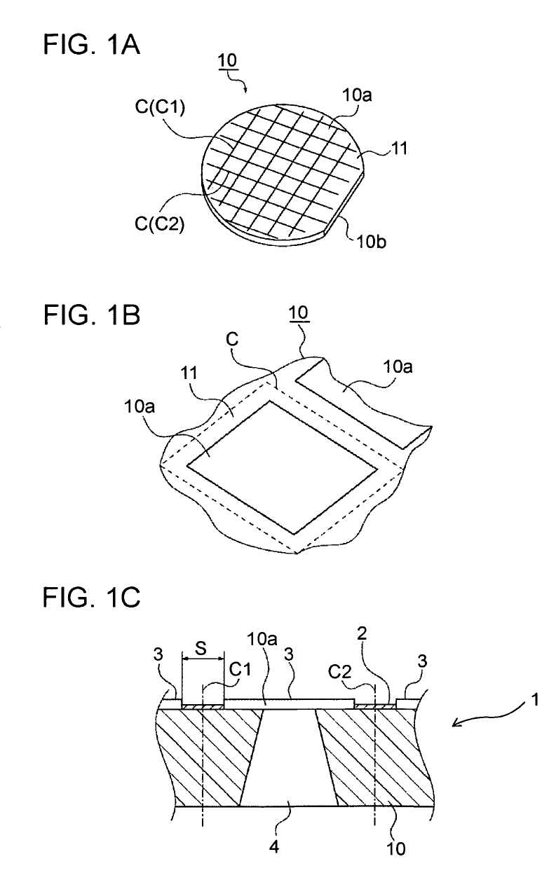

A laser beam, which can have a predetermined wavelength that can be transmitted through the silicon substrate 10, shown in FIGS. 1A-C and 2, is generated by pulsed oscillation under the predetermined conditions described below and is focused on a focal point at a predetermined depth inside the silicon substrate 10. In this way, an internal processing area is formed inside the silicon substrate 10 in a manner such that the internal processing area does not reach the substrate surface 11 where logic circuits are disposed. The internal processing area of the silicon substrate 10 is an area where alteration of the crystal structure, softening, melting, and cracking of the substrate material have been caused by focusing a laser beam on the area. Internal processing that is carried out on the silicon substrate 10, according to an exemplary embodiment of the present invention, can cause a crack to develop in the depth direction of the substrate but causes substantially no melting.

In this way, one or more internal processing areas 12 (e.g., internal cracks 12a to 12f) are formed inside the silicon substrate 10, which is provided as a member to be cut. By relatively moving the laser beam and the silicon substrate 10 in a manner such that the focal point of the laser beam scans the cutting lines C (refer to FIGS. 1A to 1C), the internal processing areas 12, i.e., cracks, are formed along the cutting lines C. Usually, the cutting lines C are not actual lines on the substrate surface 11 but are imaginary lines indicating where to cut the substrate.

According to at least one exemplary embodiment, in addition to forming the internal processing areas 12, melt processing for forming a melt area on the surface of the silicon substrate 10 and inside the silicon substrate 10 can be carried out. By carrying out melt processing, the silicon substrate 10 is melted from the cutting line C on the substrate surface 11 or immediately below the cutting line C toward the internal processing areas 12. When the melt area finally reaches a crack of an internal processing area 12 formed inside the silicon substrate 10, the silicon substrate 10 is cut. In melt processing, a laser beam, which can have a wavelength that is not absorbed inside the silicon substrate 10 but absorbed at the substrate surface 11, is focused on the substrate surface 11 to form and develop a melt area from the substrate surface 11 to inside the silicon substrate 10 while carrying out or after carrying out internal processing.

In melt processing, configured to form a melt area inside the silicon substrate 10 and to develop the melt area toward the internal processing areas 12, a laser beam, which can have a wavelength that is absorbed inside the silicon substrate 10, is focused on a focal point inside the silicon substrate 10. A cutting surface including the internal processing areas 12 is formed by moving the focal point to cut the silicon substrate 10.

At this time, a depression 11a is formed on the cutting line C on the substrate surface 11, for example, using a diamond pen. Melt processing can be carried out by focusing the laser beam inside depression 11a (i.e., at the bottom of the depression 11a) so that the depression 11a becomes the origin of the melt area.

In this way, cracks originating from an internal processing area can be prevented from developing in a direction deviating from the cutting line C on the substrate surface 11. In other words, according to this exemplary embodiment, the actual cut areas do not appreciably exceed the scribing width.

According to this exemplary embodiment, the chance of a crack originating from at tip of an internal processing area from developing in an undesirable direction is prevented or reduced. Moreover, by forming internal processing areas inside the substrate at predetermined positions by focusing a laser beam, the time required for carrying out melt processing to cut the substrate can be reduced. Minute pores in the internal processing areas release the pressure caused by the melting of the substrate material that occurs by carrying out melt processing. Thus, the amount of processing debris sprayed onto the surface of the substrate can be reduced.

[Substrate]

On the surface of the substrate 10 (e.g., silicon substrate, or any other substrate material as known by one of ordinary skill in the relevant arts and equivalents), shown in FIGS. 1A and 1B, ink discharge units and the peripheral units of an inkjet recording head are disposed as non limiting examples of logic device sections 10a. Note in the non limiting examples herein a silicon substrate 10 is referred to, however the substrate 10 can be made of any appropriate material (e.g., semiconductor, conductor, insulator). As illustrated in FIG. 1C, an oxidation film 2, which can have a thickness of about 1 μm, is formed on the surface of a 625-μm-thick silicon wafer 1 which includes a monocrystalline silicon whose surface is a (100) plane. On the oxidation film 2, nozzle layers 3 are disposed. The nozzle layers 3 are structures for discharging liquid, such as ink, and are constructed of epoxy resin with embedded logic devices and wiring for driving the liquid discharge. The components included in-the nozzle layers 3 constitute the logic devices 10a. The cutting line C includes cutting lines C1 and C2 that surround each of the logic devices 10a and that extend in two different directions orthogonal to each other with respect to the orientation flat 10b.

An opening provided as a liquid inlet (ink inlet) 4 is formed immediately below each of the nozzle layers 3, where the liquid discharge structures are embedded, by carrying out anisotropic etching of the silicon wafer 1. The nozzle layers 3 are disposed symmetric to each other with respect to the cutting lines C1 and C2 so that the silicon wafer 1 can be cut to separate each individual device chip at the final step of the production process. The cutting lines C1 and C2 are provided along the crystal orientation of the silicon wafer 1. The nozzle layers 3 are disposed adjacent to each other with a space S of about 400 μm or greater provided between each other.

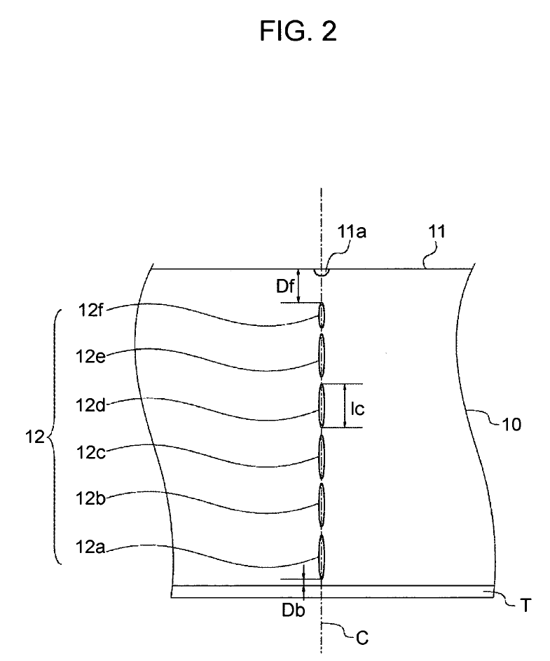

FIG. 2 illustrates a cross-sectional view of the silicon substrate 10 including the internal processing areas 12, i.e., the internal cracks 12a to 12f. The internal cracks 12a to 12f are provided along the depth direction of the silicon substrate 10 along a cutting line C on the front surface of the silicon substrate 10.

A dicing tape T is attached to the back surface of the silicon substrate 10. The dicing tape T is provided to prevent the logic devices 10a from separating from the silicon substrate 10 before completing the cutting process.

Since substantially the entire substrate surface 11 of the silicon substrate 10 is irradiated with a laser beam emitted orthogonally to the substrate surface 11, one can correct and/or reduce the deformation of the silicon substrate 10 by flattening the silicon substrate 10 by, for example, suction using a suction stage from the side the dicing tape T.

[Processing Apparatus]

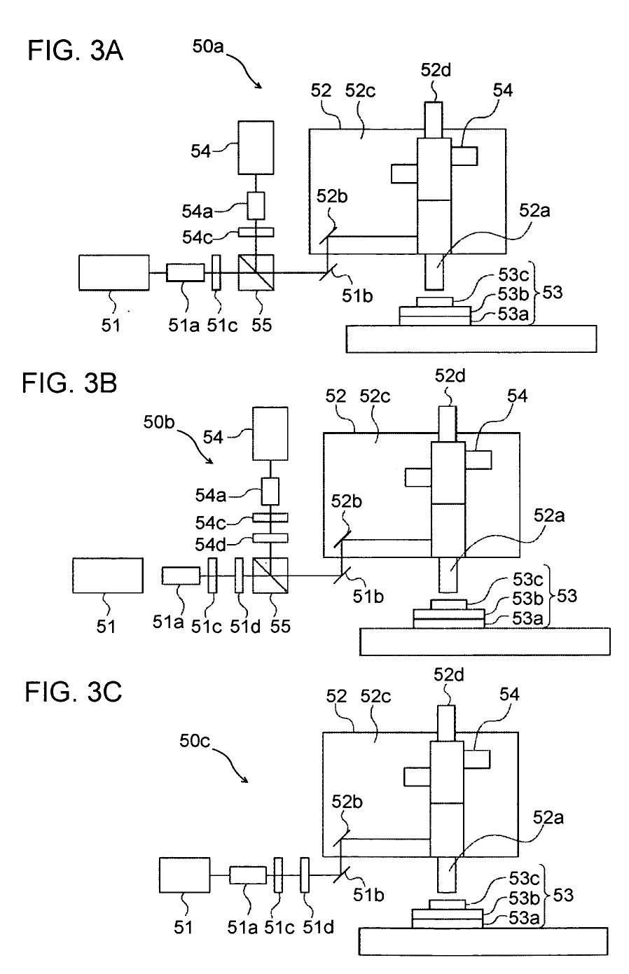

A processing apparatus that includes one (e.g., 50c) or two (e.g., 50a and 50b) laser irradiation optical systems each of which can have a light source optical system and a convergence optical system and includes a supporting apparatus configured to move the silicon substrate 10 provided as a member to be cut relative to the laser irradiation optical system will be described below with reference to FIGS. 3A to 3C.

As described with reference to FIG. 3A, at least one exemplary embodiment of the present invention is directed to a processing apparatus 50a including two laser irradiation optical systems. Here, the processing apparatus 50a includes a laser-emitting system that can be used for forming the internal processing areas 12 (i.e., internal cracks 12a to 12f) by focusing a laser beam inside the silicon substrate 10 and a laser-emitting system that can be used for forming a melt area from the substrate surface 11 to inside the silicon substrate 10 by focusing a laser beam on the substrate surface 11.

The processing apparatus 50a includes a first light source optical system including a light source 51, a beam expansion system 51a, a shutter 51c, and a second light source optical system including a light source 54, a beam expansion system 54a, a shutter 54c. The processing apparatus 50a further includes a convergence optical system including a dichroic mirror 55 for combining the laser beams from the first and second light source optical systems, a microscope objective lens 52a, and mirrors 51b and 52b for guiding the laser beam from the dichroic mirror 55 to the microscope objective lens 52a. The processing apparatus 50a also includes an automatic stage 53 including an X stage 53a, a Y stage 53b, and a Z stage 53c for fine adjustment and an alignment optical system (not shown in the drawings) for carrying out alignment with the orientation flat 10b (FIG. 1A) of the silicon substrate 10 provided as a workpiece.

The light source 51 emits a basic wave (e.g., 1,064 nm) of a pulsed (e.g., yttrium, aluminum, and garnet (YAG)) laser beam. The pulse width is in the range of about 15 to 1,000 nsec. The frequency is in the range of 10 to 100 kHz. Laser processing is carried out within an energy range of 2 to 100 μJ. The laser beam emitted from the light source 54 can be a higher (e.g., third) harmonic of the laser beam emitted from the light source 51. A non limiting example of a wavelength of the beam emitted from the light source 54 is 355 nm. The frequency is in the range of about 10 to 100 kHz. The laser beam from the light source 51 is set to a wavelength that passes through the silicon substrate 10. The laser beam from the light source 54 is set to a wavelength that is absorbed at the surface of the silicon substrate 10.

The dichroic mirror 55 is configured to emit two laser beams having different wavelengths along the same optical axis. The shutters 51c and 54c are configured to switch the light source to be used.

By changing the light source 54 to a light source that is the same as the light source 51, the first and second light source optical systems can use laser beams, which can have the same wavelength. In such a case, the polarization planes of the two laser beams are matched when combing the laser beams. In order to match the polarization planes, polarizing plates 51d and 54d corresponding to the wavelength of the laser beams emit from the first and second light source optical systems can be disposed, and a polarized light beam splitter 55b is used as a device for combining the light paths of the laser beams instead of the dichroic mirror 55 (FIG. 3B) in the processing apparatus 50b. By matching the optical axes of the laser beams from the two light sources after they are emitted from the polarized light beam splitter 55b, the laser beams from the two light sources are combined. When combining the laser beams, a λ/2 plate can used to adjust the polarization plane if the laser beams emitted from the light sources 51 and 54 are linearly polarized beams.

The above-described internal processing and melt processing can be carried out by using one light source at the same wavelength and controlling the oscillation condition of the light source. Such control will be described with reference to FIG. 3C. The processing apparatus 50c shown in FIG. 3C has the same structure as the processing apparatus 50c shown in FIGS. 3A and 3B except that, instead of two light source optical systems, it only includes one light source optical system including the light source 51, the beam expansion system 51a, the mirror 51b, and the shutter 51c. For example, the light source 51 emits a basic wave (1,064 nm) of a pulsed YAG laser beam. The pulse width is in the range of about 15 to 1,000 nsec. The frequency is in the range of about 10 to 100 kHz.

By controlling the oscillation of a single light source in a manner such that the oscillation is switched between pulsed oscillation and continuous oscillation, internal processing can be carried out by a laser beam generated by pulsed oscillation and melt processing can be carried out by a laser beam generated by continuous oscillation. Pulsed oscillation generates a laser beam that can be used for internal processing, whereas, continuous oscillation generates a laser beam that can be used for melting the substrate without forming internal cracks.

In the above-described processing apparatus 50a-c, the laser beam used for forming the internal cracks 12a to 12f is selected on the basis of the spectral transmittance of the silicon substrate 10. Any type of laser can be used so long as the laser beam facilitates forming an intense electric field at a focal point and is within a wavelength range that passes through the substrate material (e.g., silicon, SiO2, other substrate materials as known by one of ordinary skill in the relevant arts and equivalents). The basic wave of the pulsed YAG laser beam used in this exemplary embodiment passes through the silicon substrate 10. The flux of light incident on the substrate surface 11 is refracted inside the silicon substrate 10 and is focused on a focal point at a predetermined depth inside the silicon substrate 10. Thus, an internal crack (i.e., one of the internal cracks 12a to 12f) is formed in an area including the focal point.

In at least one exemplary embodiment the laser beam used for melting the silicon substrate 10 from the surface has a small spot diameter when focused so that the amount of debris produced is reduced.

[Internal Processing]

A method of forming the internal processing areas 12 (the internal cracks 12a to 12f) using the processing apparatus 50a-c, which can have the above-described structure, will be described below.

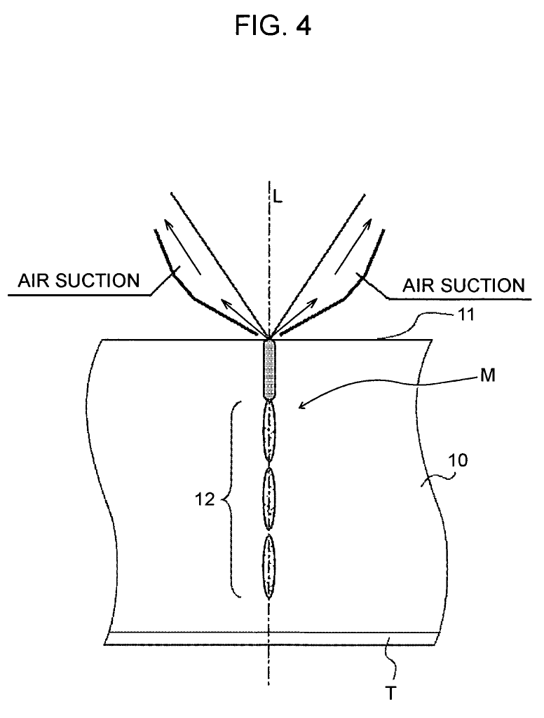

When a laser beam L (FIG. 4) generated by pulsed oscillation is emitted from the first light source optical system and is focused on a focal point inside the silicon substrate 10, the crystalline structure of silicon partially changes at and around the focal point. Thus, an internal crack (i.e., one of the internal cracks 12a to 12f) is formed. According to experiment, the length of the cracks can vary and in the experiment(s) was in the range of about 2 to 100 μm.

As described above, internal processing is carried out immediately below and along the cutting line C by forming an internal crack at a point inside the silicon substrate 10 and moving the focal point relative to the silicon substrate 10 along the cutting line C. Note that the alternative of moving the substrate 10 (e.g., in a Z direction) without moving the focal point is also within at least one exemplary embodiment.

The silicon substrate 10 provided as a workpiece can be move in the X and Y directions on a horizontal plane by moving the automatic stage 53 in the X and Y directions. The silicon substrate 10 can be moved in the Z direction, i.e., the direction of the optical axis (the depth direction or the thickness direction of the silicon substrate 10), by providing the Z stage 52c on the side of the automatic stage 53 or a convergence optical system 52. The Z stage 52c changes the relative distance between the convergence optical system 52 and the workpiece.

The convergence optical system 52 includes an observation camera 52d, which can have a filter corresponding to the laser output, so that it is conjugate with the irradiation point on the workpiece. For providing light for observation, a relay lens can be used to provide Kohler illumination by disposing a light source at the entrance pupil of the microscope objective lens 52a used for focusing.

In addition to the above-described observation optical system, an auto-focus (AF) optical apparatus 56 can be used to measure the distance to the workpiece. The AF optical apparatus 56 determines the contrast of the image captured by the observation camera 52d and measures the focus and the tilt from the determined contrast value. Additionally, the distance to the workpiece can be measured to measure the contrast in order to determine the optimal position. Moreover, AF control can be carried out by emitting and reflecting a laser beam at the substrate surface 11.

As described above, the length of a crack formed at a focal point can vary for example from about 2 to 100 μm, wherein the thickness of the silicon substrate 10 can also vary and for this example is 625 μm. Therefore, to cut the silicon substrate 10, internal processing can be carried out multiple times. The internal processing areas 12 are formed in order from a position furthest away from the front surface of the silicon substrate 10 (i.e., a position close to the back surface of the silicon substrate 10) towards the front surface of the silicon substrate 10 at points where the laser beam is incident on. In this way, the laser beam does not pass through previously formed internal processing areas, and, therefore, a plurality of internal processing areas 12 can be formed by a laser beam that is not altered by passing through other internal processing areas. When carrying out internal processing, the internal cracks in the vicinity of the substrate surface 11 are formed so that they do not reach the substrate surface 11. In this way, the logic device sections 10a disposed on the substrate surface 11 can be prevented from being damaged. Furthermore, internal processing is not carried out if the processing conditions might cause an already existing internal crack to develop and reach the substrate surface 11 due to heat generated by a laser beam emitted for the internal processing.

However, this is not applicable inside the silicon substrate 10, and, as illustrated in FIG. 2, the internal cracks 12a to 12f can be formed discontinuously along the depth direction of the silicon substrate 10 or the internal cracks can be connected (such a connected state is not shown in the drawings). For the internal crack 12f that is closest to the substrate surface 11 of the silicon substrate 10, the distance Df from the substrate surface 11 to the tip of the internal crack 12f can vary and for this example is in the range of about 10 to 100 μm. The internal crack 12f is formed at a position where it does not communicate with the substrate surface 11.

The length of an internal crack in the depth direction can also vary in the exemplary embodiments and in this example is in the range of about 60 to 70 μm. The internal cracks can be formed by moving the focal point from the substrate surface 11 deeper inside the silicon substrate 10 by increments of about 95 μm. The distance between the internal cracks can be adjusted by determining how far the focal point can be moved along the depth direction. The internal crack 12a at the deepest position (i.e., a position closest to the back surface of the silicon substrate 10) is formed so that the distance Db from the lower tip of the internal crack 12a to the back surface of the silicon substrate 10 is about 50 μm.

[Melt Processing 1]

Next, a method of forming a melt area on the substrate surface 11 by focusing a laser beam emitted from the second light source optical system on the substrate surface 11 and developing the melt area towards the internal processing areas 12 formed inside the silicon substrate 10 will be described.

Melt processing is carried out by setting the focal point of the microscope objective lens 52a of the convergence optical system 52 at the surface of an object, (e.g., by setting the focal point of the laser beam at the substrate surface 11 of the silicon substrate 10). A melt area M is formed by focusing a laser beam L that is absorbed by the substrate surface 11 of the silicon substrate 10 on the substrate surface 11. The melt area M reaches the back surface from the front surface of the silicon substrate 10. By carrying out melt processing, a through-hole can be formed in the silicon substrate 10 (e.g., which can be of various thickness but for this example is 625 μm thick). Energy supplied by the laser beam L incident on the substrate surface 11 is transmitted inside the silicon substrate 10 along the direction of the optical axis, causing the melt area M to increase and develop. In melt processing, the wavelength of the laser beam emitted from the light source 54 is shorter than the wavelength of the laser beam used in the above-described internal processing. In this non-limiting example, a YAG laser with a 355 nm wavelength can be used.

As illustrated in FIG. 4, melt processing is carried out in a manner such that the melt area M formed at the incident point develops in the thickness direction (i.e., inside the silicon substrate 10 along the depth direction).

When carrying out internal processing on a position several ten micrometers from the substrate surface 11, in some cases, the substrate surface 11 melts when the laser beam used for the internal processing passes through, and a depression 11a (FIG. 2) is formed. Such a depression 11a can be present when carrying out melt processing. If a depression 11a is present, the laser beam used for melt processing is emitted at the bottom of the depression 11a.

In melt processing, the melted material is dispersed and the melt area protrudes in the vicinity of the laser irradiation area. Such dispersion and/or protrusion can be the cause of defective industrial products. Therefore, one can minimize or reduce the occurrence of such dispersion and/or protrusion. Consequently, the smaller the volume processed by laser (which is determined by the spot diameter multiplied by the thickness of the absorption layer), the more useful in reducing the dispersion and/or protrusion. When the silicon spectral transmittance is taken into consideration, the shorter the wavelength, the higher the absorbance is. When the convergence optical system is taken into consideration, the shorter the wavelength, the smaller the spot diameter is. Accordingly, the wavelength of the laser beam used for melt processing can be set shorter than the wavelength of the laser beam used for internal processing.

To reduce the amount of dispersed material attaching to the substrate surface 11, it is effective to suck out the gas in the vicinity of the incident point. In particular, though not exclusively, by sucking out the gas near the surface around the incident point, the amount of dispersed debris generated by laser processing can be reduced, and contamination, by debris, of the microscope objective lens 52a can be prevented or reduced. However, when the flow rate of the gas in the vicinity of the incident point exceeds a predetermined value because of the suction, a change in the refractive index of the gas in the vicinity of the incident point can effect the optical characteristics of the apparatus. When gas other than air is present in the vicinity of the incident point, one can select the microscope objective lens 52a in accordance with the refractive index of the gas.

As the columnar melt area M formed by melt processing develops inside the silicon substrate 10 from the substrate surface 11, the melt area M reaches the internal processing areas 12 formed in advance, as illustrated in FIG. 4. The internal processing areas 12 include minute pores, and the melt area M develops inside the silicon substrate 10 (e.g., toward the back surface of the silicon substrate 10) from the front surface of the silicon substrate 10 along the pores of the internal processing areas 12. When the internal processing areas 12 were formed, the internal processing has caused the silicon substrate 10 to undergo alterations, such as melting and hardening, in the internal processing areas 12. When the melt area M reaches the internal processing areas 12 from the substrate surface 11, the internal processing areas 12 melts and hardens again. Since the internal processing areas 12 have already undergone a changed from a monocrystalline state to a melted state, remelting easily occurs. Therefore, the speed of a melt area developing along the thickness direction while taking in the internal processing areas 12 is faster than the speed of a melt area developing in an area where internal processing areas are not formed because a chain reaction is caused to melt the silicon substrate 10 in the thickness direction.

The melt area M formed by carrying out melt processing develops through the lower edge of the internal processing areas 12 (i.e., the edge of the inner processing area closest to the back surface of the silicon substrate 10) that extend in the thickness direction and toward the back surface of the silicon substrate 10. Thus, the silicon substrate 10 can be cut when the melt area M reaches the back surface of the silicon substrate 10. The silicon substrate 10 can otherwise be cut by forming a crack between the tip of the melt area M and the back surface of the silicon substrate 10 when the tip of the melt area M approaches the back surface of the silicon substrate 10.

[Melt Processing 2]

According to another exemplary embodiment described below, the same laser beam as that used for internal processing, i.e., the laser beam having a wavelength that is transmitted through the silicon substrate 10 used in the above-described first light source optical system, is also used for the second light source optical system (FIG. 3B). In this case, the laser beam emitted from the first light source optical system forms internal processing areas in the same way as described above. However, the laser beam from the second light source optical system is emitted under conditions in which internal processing areas are not formed. In this case, the laser beam emitted from the second light source optical system is not used for forming internal processing areas 12 but can be used for forming a melt area M.

Instead, as illustrated in FIG. 3C, the oscillation condition of the light source 51 can be controlled so that internal processing areas 12 are first formed and then, after changing the oscillation condition, a melt area M is formed.

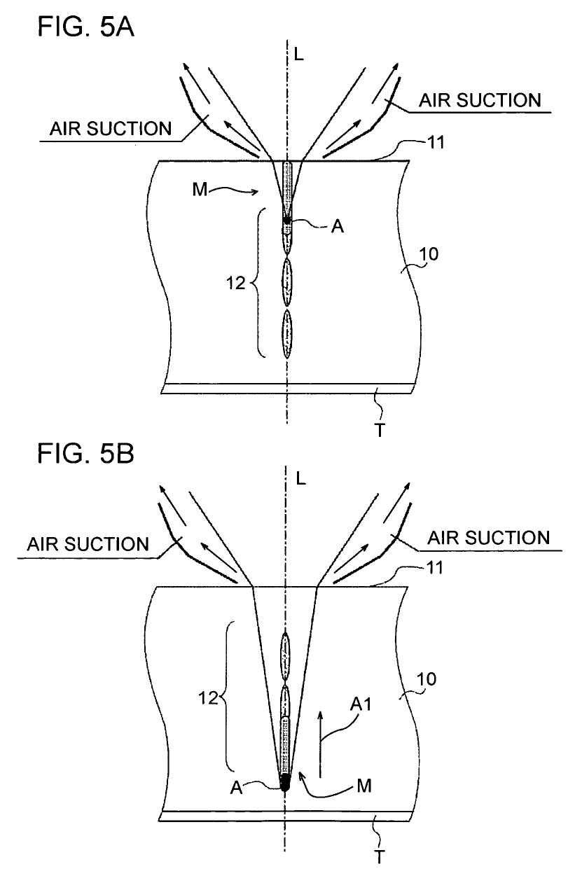

A focal point A (FIGS. 5A and 5B) of the laser beam is moved along the internal processing areas in the thickness direction of the silicon substrate 10. In this way, the melt area M is extended in the thickness direction of the silicon substrate 10, and the internal processing areas 12 are melted. Thus, the internal processing areas 12 and the melt area M are connected, cutting the silicon substrate 10 in two.

To guide the melt area M inside the silicon substrate 10, a laser beam having a wavelength that is absorbed inside the silicon substrate 10 is focused on a focal point inside the silicon substrate 10, and the focal point is scanned (moved) in the thickness direction of the silicon substrate 10. At this time, the emission conditions of the laser beam are set such that the inside portion of the silicon substrate 10 melts. The conditions are not set to form internal processing areas by multiphoton absorption. Therefore, the laser beam used in this case can be generated by continuous oscillation. Here, the laser beam is emitted so that the focal point A moves from the front surface of the silicon substrate 10 to the back surface so that the melt area M develops from the front surface of the silicon substrate 10 to the back surface.

When the melt area M develops from the front surface into the silicon substrate 10, the melt area M reaches the internal processing areas 12 that have already been formed, as illustrated in FIG. 5A. The internal processing areas 12 include minute pores, and the melt area M develops from the front surface of the silicon substrate 10 along the pores. At this time, by moving the position of the focal point A along the internal processing areas 12, the development of the melt area M is guided in the thickness direction of the silicon substrate 10. The internal processing areas 12 are melted and hardened again. Since the internal processing areas 12 have already undergone a changed from a monocrystalline state to a melted state, remelting easily occurs.

At this time, a method in which the focal point A is moved (A1) in a direction from the back surface of the silicon substrate 10 toward the front surface so that the melt area M develops from the tip of the internal processing areas 12 closest to the back surface can be employed (FIG. 5B). According to this method, a plurality of internal processing areas 12 are formed along the thickness direction of the silicon substrate 10, and the melt area M develops from the internal processing area closest to the back surface toward the internal processing area closest to the front surface.

In at least one exemplary embodiment, one can contemporaneously use the first and second light source optical systems to contemporaneously form the internal processing areas 12 and the melt area M. In this way, processing time can be reduced.

According to this exemplary embodiment, the cross-section of the silicon substrate 10 includes a melt area M extending from the front surface to back surface of the silicon substrate 10. At a cross-section taken along the area where internal processing areas 12 are formed has a different structure compared to a cross-section taken along an area where internal processing areas are not formed (i.e., an area where only melt processing is carried out) because the formation speed of the melt area M is faster in the area where the internal processing areas 12 are formed.

According to this exemplary embodiment, by properly operating the automatic stage 53 of the processing apparatus 50a-c, at least one internal processing areas is formed immediately below the cutting line C and the focal point of a laser beam used for forming the melt area M inside the silicon substrate 10 is moved orthogonally to the substrate surface 11. In this way, the silicon substrate 10 can be efficiently cut without deviating from the cutting line C.

[Melt Processing 3]

The processing apparatus 50a-c according to at least one exemplary embodiment of the present invention facilitates setting at least one focal point immediately below the cutting line C of the silicon substrate 10 to an accuracy of about one micrometer by properly operating the automatic stage 53. It is also possible to estimate the length of a crack formed by internal processing in the depth direction of the silicon substrate 10 depending on the oscillation condition of the laser. In this way, it is possible to estimate the distribution of at least one crack formed inside the silicon substrate 10 by internal processing.

According to at least one exemplary embodiment, the above-described melt processing is carried out to connect the substrate surface 11 and the cracks formed immediately below the substrate surface 11 by internal processing (i.e., internal processing areas 12) and to connect each of the cracks (internal processing areas 12) formed by internal processing.

For example, the second light source optical system, described with reference to FIG. 3B, can be used to focus a laser beam that passes through the silicon substrate 10 on the substrate surface 11 or on a focal point in the area immediately below the substrate surface 11 under oscillation conditions in which a melt area is formed but internal processing areas are not. Then, a melt area M is formed by moving the focal point of the laser beam to a crack inside the silicon substrate 10 formed when internal processing was carried out for the first time to the silicon substrate 10. When the focal point reaches the position that is estimated to be the upper tip of the first crack, the formation of the melt area M is stopped. The formation of the melt area is restarted from the lower up tip of the crack by focusing the laser beam again. Then, the focal point is moved in the depth direction again such that the melt area M develops inside the silicon substrate 10 until the focal point reaches the tip of a crack formed when internal processing was carried out for the second time. Such processes are alternately repeated until the back surface of the silicon substrate 10 is reached, and the silicon substrate 10 is cut. Instead, the silicon substrate 10 can be cut because of the formation of a new crack between the development direction tip of a melt area formed close to the back surface of the silicon substrate 10 and the back surface of the silicon substrate 10.

Such method of cutting in accordance with at least one exemplary embodiment controls the oscillation condition of the only light source 51, as illustrated in FIG. 3C. For example, after forming the internal processing areas 12, the oscillation condition can be changed to form a melt area connecting the substrate surface 11 and a crack and connecting each of the cracks.

A cross-section of silicon substrate 10 according to an exemplary embodiment of the present invention includes alternating layers in the depth direction constructed of cracks formed by internal processing and melt areas formed between a crack and the substrate surface 11 and between cracks provided.

According to at least one exemplary embodiment, by properly operating the automatic stage 53 of the processing apparatus 50, at least one internal processing areas is formed immediately below the cutting line C and the focal point of the laser beam used for forming the melt area M inside the silicon substrate 10 is moved orthogonally to the substrate surface 11. In this way, the silicon substrate 10 can be efficiently cut without deviating from the cutting line C.

According to at least one exemplary embodiment, reduction of processing time and stable laser emission along the cutting line is possible by forming internal processing areas inside the substrate by focusing the laser beam. Minute pores included in the internal processing areas release the pressure built at the melt area caused by laser processing carried out from the substrate surface. Thus, the amount of processing debris sprayed onto the substrate surface can be reduced. Additionally air suction can be employed to remove any processing debris (FIGS. 5A-B).

[Post-Processing]

By carrying out internal processing and melt processing, part of the front surface of the silicon substrate 10 and part of the back surface of the silicon substrate 10 are connected with each other. However, in many cases, the connection is not satisfactory for separating each of the logic devices 10a.

Accordingly, the silicon substrate 10 on which the above-described processing is carried out is disposed on a resilient rubber sheet 60 which includes, for example, silicone rubber or fluoro-rubber, so that the back side of the silicon substrate 10 is mounted on the dicing tape T. Then, a stainless roller 61 can be used to apply an external force for compressing the silicon substrate 10 from the back side through the dicing tape T. In this way, each individually logic devices 10a is separated from the silicon substrate 10.

As described above, by forming internal processing areas by focusing a laser beam inside a member (substrate) to be cut, the time required for cutting the member can be reduced. Moreover, by forming a melt area by moving the focal point of the laser beam, the member can be cut along a line connecting the surface of the member and the internal processing areas without deviating from the cutting line on the surface of the member.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures and functions.

This application claims the benefit of Japanese Application No. 2005-138469 filed May 11, 2005, which is hereby incorporated by reference herein in its entirety.

What is claimed is:

1. A method of preparing a member for cutting by irradiating the member with a laser beam, the method comprising the steps of:
forming at least one internal processing area extending inside the member in a depth direction of the member, wherein the internal processing area is formed by focusing the laser beam inside the member; and
forming a melt area extending in the depth direction of the member, wherein the melt area is formed by focusing the laser beam at the surface of the member or inside the member.

2. The method according to claim 1, wherein, the laser beam used for forming the internal processing area inside the member is set to a wavelength that passes through the member, and
the laser beam used for forming the melt area by focusing the laser beam at the surface of the member is set to a wavelength that is absorbed at the surface of the member.

3. The method according to claim 1, wherein, the laser beam used for forming the internal processing area inside the member is set to a wavelength that passes through the member, and
the laser beam used for forming the melt area by focusing the laser beam at the surface of the member or inside the member is set to a wavelength that passes through the member.

4. The method according to claim 3, wherein the laser beam used for forming the internal processing area and the laser beam used for forming the melt area are emitted from the same light source optical system.

5. The method according to claim 3, wherein,
the laser beam used for forming the internal processing area is generated by pulsed oscillation, and
the laser beam used for forming the melt area is generated by continuous oscillation.

6. The method according to claim 5, wherein the laser beam used for forming the internal processing area and the laser beam used for forming the melt area are emitted from the same light source optical system.

7. The method according to claim 2, wherein the internal processing area melts as the melt area develops through the member.

8. The method according to claim 3, wherein the internal processing area melts as the melt area develops through the member.

9. The method according to claim 2, wherein,
the melt area connects the surface of the member and a first internal processing area, and
the melt area connects the first internal processing area with a second internal processing area.

10. The method according to claim 3, wherein,
the melt area connects the surface of the member and a first internal processing area, and
the melt area connects the first internal processing area and a second internal processing area.

11. A method of separating function elements by separating a plurality of function elements from a substrate by irradiating a portion of the function elements with a laser beam, the method comprising the steps of:
forming at least one internal processing area extending inside the substrate in the depth direction of the substrate, wherein the internal processing area is formed by focusing the laser beam inside the substrate;
forming a melt area extending in the depth direction of the substrate, wherein the melt area is formed by focusing the laser beam at the surface of the substrate or inside the substrate; and
separating the function elements from the substrate.

12. The method according to claim 11, wherein,
the laser beam used for forming the internal processing area inside the substrate is set to a wavelength that passes through the substrate, and
the laser beam used for forming the melt area by focusing the laser beam at the surface of the substrate is set to a wavelength that that is absorbed at the surface of the substrate.

13. The method according to claim 11, wherein,
the laser beam used for forming the internal processing area inside the substrate is set to a wavelength that passes through the substrate, and
the laser beam used for forming the melt area by focusing the laser beam at the surface of the substrate or inside the substrate is set to a wavelength that passes through the substrate.

14. The method according to claim 13, wherein the laser beam used for forming the internal processing area and the laser beam used for forming the melt area are emitted from the same light source optical system.

15. The method according to claim 13, wherein,
the laser beam used for forming the internal processing area is generated by pulsed oscillation, and
the laser beam used for forming the melt area is generated by continuous oscillation.

16. The method according to claim 15, wherein the laser beam used for forming the internal processing area and the laser beam used for forming the melt area are emitted from the same light source optical system.

17. The method according to claim 12, wherein the internal processing area melts as the melt area develops through the substrate.

18. The method according to claim 13, wherein the internal processing area melts as the melt area develops through the substrate.

19. The method according to claim 12, wherein,
the melt area connects the surface of the substrate and a first internal processing area, and
the melt area connects the first internal processing area with a second internal processing area.

20. The method according to claim 13, wherein,
the melt area connects the surface of the substrate and a first internal processing area, and
the melt area connects the first internal processing area and a second internal processing area.
